(19) United States
(12) Patent Application Publication
(10) Pub. No.: US 2026/0321315 A1
(43) Pub. Date: Oct. 15, 2026

(54) DUAL XDL ARCHITECTURE FOR HIGH BANDWIDTH NAND MEMORY DEVICES

(71) Applicant: Sandisk Technologies, Inc., Milpitas, CA (US)

(72) Inventors: Sajal MITTAL, Bangalore (IN); Indana SAINATH, Bangalore (IN); Pradeep ANANTULA, Bangalore (IN)

(73) Assignee: Sandisk Technologies, Inc., Milpitas, CA (US)

(21) Appl. No.: 19/179,207

(22) Filed: Apr. 15, 2025

(51) Int. Cl. G11C 16/26; G11C 16/10

(52) U.S. Cl. CPC G11C 16/26; G11C 16/102; G11C 2207/06

(57) ABSTRACT

An apparatus is provided that includes a memory die including a memory array having a plurality of non-volatile memory cells, a first set of transfer data latches coupled to the memory array, and a second set of transfer data latches coupled to the memory array. The first set of transfer data latches is configured exclusively for a first type of memory operation, and the second set of transfer data latches is configured exclusively for a first type of memory operation.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may be non-volatile memory or volatile memory. A non-volatile memory allows information to be stored and retained even when the non-volatile memory is not connected to a source of power (e.g., a battery).

Non-volatile memory devices include one or more memory chips having multiple arrays of memory cells. The memory arrays may have associated decoders and circuits for performing read, write, and erase operations. Memory cells within the arrays may be arranged in horizontal rows and vertical columns. Each row may be addressed by a word line, and each column may be addressed by a bit line. Data may be loaded into columns of the array using a series of data busses. Each column may hold a predefined unit of data, for instance, a word encompassing two bytes of information.

In some applications, semiconductor memory is used to store very large amounts of data that are repeatedly accessed (e.g., read) very rapidly. For example, in some machine learning applications, large language models that include a terabyte (or more) of data must be stored in memory and retrieved at a very high data rate. Accordingly, such applications require very high bandwidth and low power.

Currently, high bandwidth volatile memory devices (e.g., DRAM memory devices called “high bandwidth memory” or “HBM”) are used for such applications. Because of explosive growth for artificial intelligence applications, demand for HBM has dramatically increased and existing inventory from the HBM vendors has been exhausted or already allocated. Also, non-volatile memory (e.g., NAND) is significantly less expensive than DRAM, and thus this situation creates a good opportunity for high bandwidth NAND (referred to herein as high bandwidth flash, or “HBF”) memories as a viable alternative to HBM. However, some technical challenges remain for providing HBF memory devices.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a simplified block diagram depicting portions of memory die 200 of FIG. 2A coupled to the memory controller of FIG. 1.

FIG. 2C is a block diagram of one embodiment of an integrated memory assembly.

FIG. 2D is a simplified block diagram depicting portions of the memory die and control die of FIG. 2C coupled to the memory controller of FIG. 1

FIGS. 3A and 3B depict different embodiments of integrated memory assemblies.

FIG. 4A is a perspective view of a portion of one embodiment of a monolithic three dimensional memory array.

FIG. 4B is a block diagram of one embodiment of a memory array having four planes.

FIG. 4C depicts a top view of a portion of one embodiment of a block of memory cells.

FIG. 4D depicts a cross sectional view of a portion of one embodiment of a block of memory cells.

FIG. 4E depicts a cross sectional view of a portion of one embodiment of a block of memory cells.

FIG. 4F is a cross sectional view of one embodiment of a vertical column of memory cells.

FIG. 4G is a schematic of a plurality of NAND strings in multiple regions of a same block.

FIG. 5 is a block diagram of one embodiment of a memory array having four planes.

FIG. 6A is a simplified block diagram depicting a portion of the memory die of FIG. 2A.

FIG. 6B is a simplified block diagram depicting an alternative portion of the memory die of FIG. 2A.

FIG. 7A is a simplified diagram of an example series of commands and addresses sent from a memory controller to the portion of a memory die of FIG. 6A.

FIG. 7B is a simplified diagram of an example series of commands and addresses sent from a memory controller to the alternative portion of a memory die of FIG. 6B.

FIG. 7C is a simplified diagram of another example series of commands and addresses sent from a memory controller to the alternative portion of a memory die of FIG. 6B.

FIG. 8 is a flow diagram of a process 800 for processing program and read operations in a memory array of non-volatile memory cells.

### DETAILED DESCRIPTION

Technology is described to improve NAND memory die throughput. In an embodiment, a memory architecture of a memory die including a memory array includes two separate sets of transfer data latches. In an embodiment, the memory die includes a first set of transfer latches for write operations to the memory array and a separate second set of transfer latches for read operations from the memory array. In an embodiment, a memory controller coupled to the memory die can perform array read and write operations in parallel from a single plane or multiple planes. Without wanting to be bound by any particular theory, it is believed that the described architecture may hide NAND latencies under high-speed data transfers and may improve bus efficiency and overall throughput which is helpful for designing HBF memories.

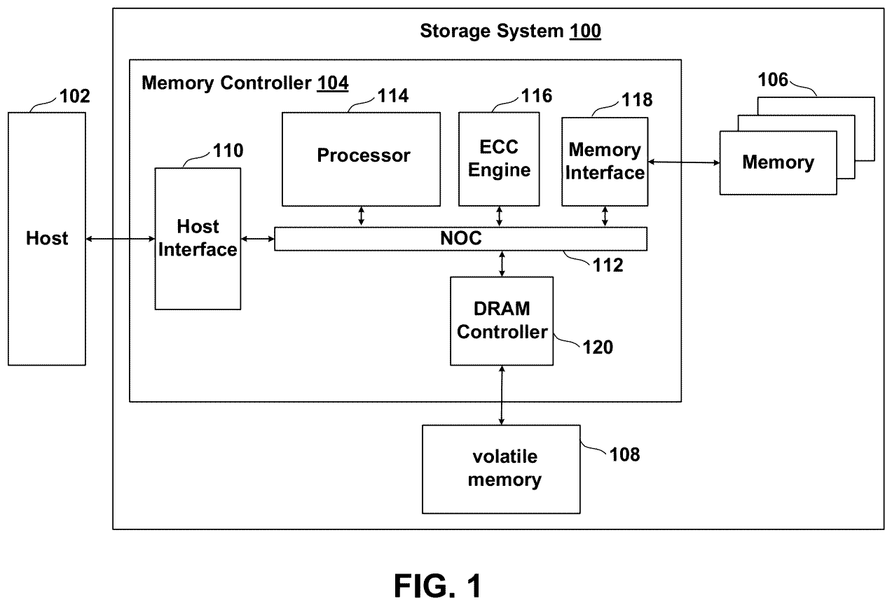

FIG. 1 is a block diagram of one embodiment of a storage system 100 that implements the proposed technology described herein. In an embodiment, storage system 100 is a solid state drive (“SSD”). Storage system 100 also can be a memory card, USB drive or other type of storage system. The proposed technology is not limited to any one type of memory system.

Storage system 100 is connected to a host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 104 connected to non-volatile memory 106 and local high speed volatile memory 108 (e.g., DRAM). Local high speed volatile memory 108 is used by memory controller 104 to perform certain functions. For example, local high speed volatile memory 108 stores logical to physical address translation tables (“L2P tables”).

Memory controller 104 includes a host interface 110 that is connected to and in communication with host 102. In an embodiment, host interface 110 implements a NVM Express (NVMe) over PCI Express (PCIe). Other interfaces can also be used, such as SCSI, SATA, etc. Host interface 110 also is connected to a network-on-chip (NOC) 112.

A NOC is a communication subsystem on an integrated circuit. NOC's can span synchronous and asynchronous clock domains or use un-clocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs.

The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 112 can be replaced by a bus.

Connected to and in communication with NOC 112 is a processor 114, an ECC engine 116, a memory interface 118, and a DRAM controller 120. DRAM controller 120 is used to operate and communicate with local high speed volatile memory 108 (e.g., DRAM). In other embodiments, local high speed volatile memory 108 can be SRAM or another type of volatile memory.

Processor 114 performs the various controller memory operations, such as programming, erasing, reading, and memory management processes. In an embodiment, processor 114 is programmed by firmware. In other embodiments, processor 114 is a custom and dedicated hardware circuit without any software. Processor 114 also implements a translation module, as a software/firmware process or as a dedicated hardware circuit.

In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 104 (e.g., the translation module) performs address translation between the logical addresses used by the host and the physical addresses used by the memory die.

One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables.

Instead, the logical address to physical address tables (or L2P tables) can be any type of data structure. In some examples, the memory space of a storage system is so large that the local memory 108 cannot hold all of the L2P tables. In such a case, the entire set of L2P tables are stored in non-volatile memory 106 and a subset of the L2P tables are cached (L2P cache) in the local high speed volatile memory 108.

ECC engine 116 performs error correction services. For example, ECC engine 116 performs data encoding and decoding, as per the implemented ECC technique. In an embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Memory interface 118 communicates with non-volatile memory 106. In an embodiment, memory interface provides a Toggle Mode interface. Other interfaces also can be used. In some example implementations, memory interface 118 (or another portion of controller 104) implements a scheduler and buffer for transmitting data to and receiving data from one or more memory die.

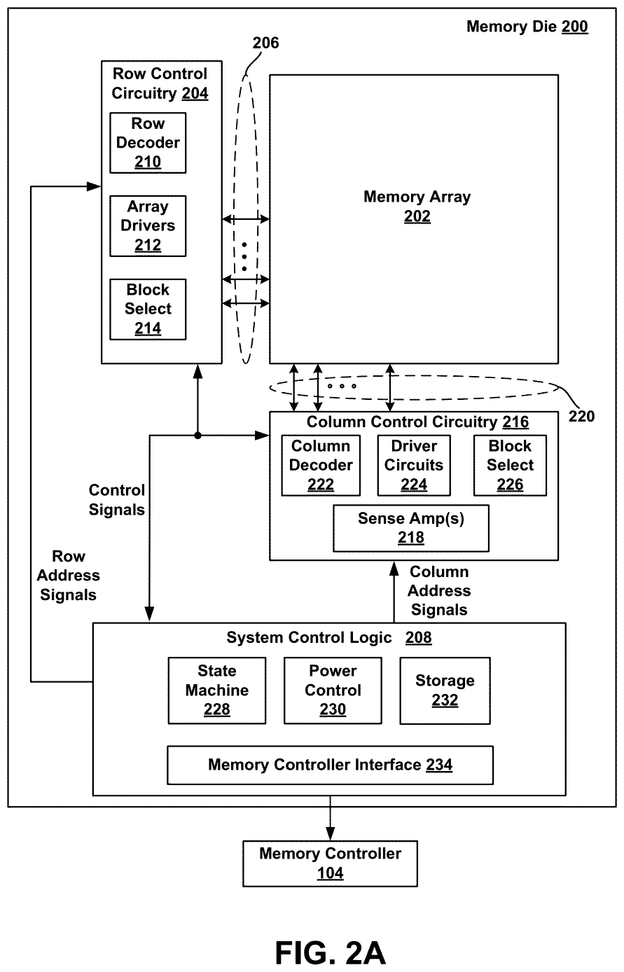

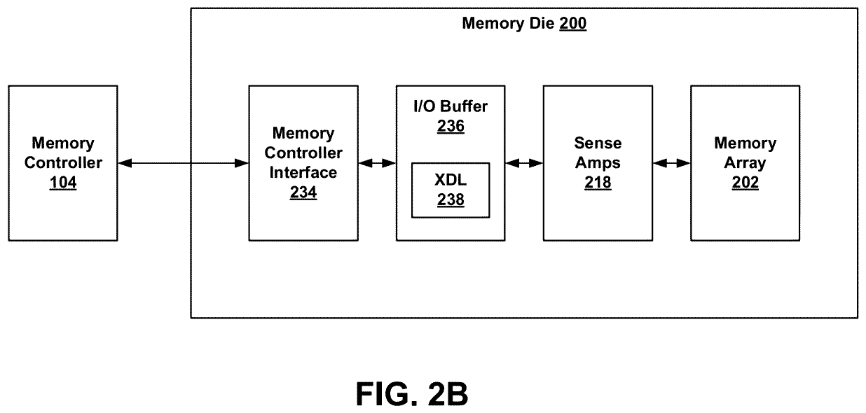

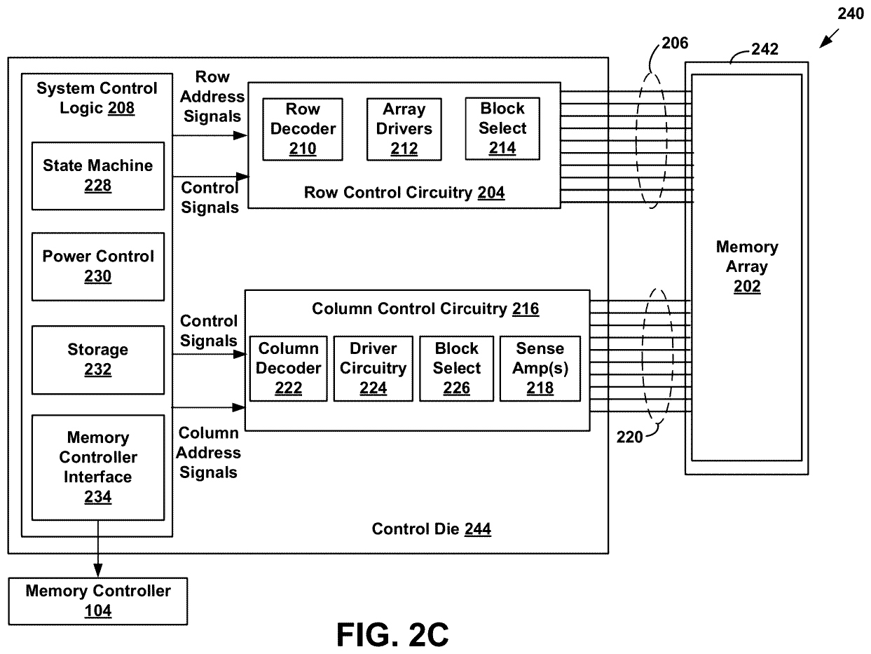

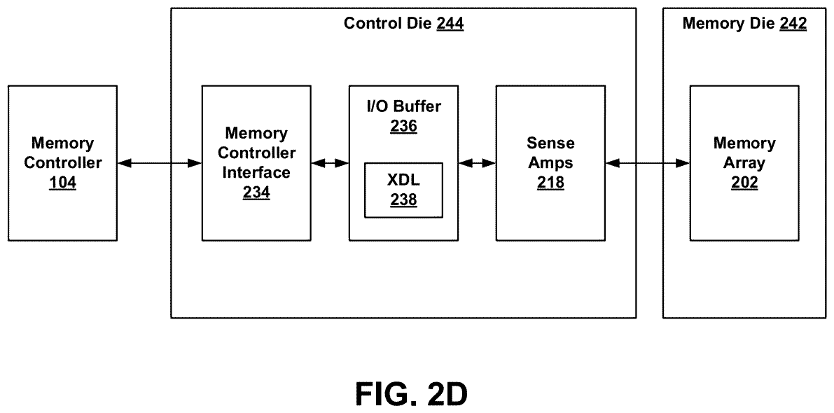

In an embodiment, non-volatile memory 106 includes one or more memory die. FIG. 2A is a functional block diagram of an embodiment of a memory die 200 that includes non-volatile memory 106. Each of the one or more memory die of non-volatile memory 106 can be implemented as memory die 200 of FIG. 2A. The components depicted in FIG. 2A are electrical circuits.

Memory die 200 includes a memory array 202 that can include non-volatile memory cells, as described in more detail below. The array terminal lines of memory array 202 include various layer(s) of word lines organized as rows, and various layer(s) of bit lines organized as columns. However, other orientations also can be implemented.

Memory die 200 includes row control circuitry 204, whose outputs 206 are connected to respective word lines of the memory array 202. Row control circuitry 204 receives a group of M row address signals and one or more various control signals from system control logic circuit 208, and typically may include such circuits as row decoders 210, array terminal drivers 212, and block select circuitry 214 for both reading and writing (programming) operations.

Row control circuitry 204 also may include read/write circuitry. Memory die 200 also includes column control circuitry 216 including sense amplifier(s) 218 whose input/outputs 220 are connected to respective bit lines of memory array 202. Although only a single block is shown for memory array 202, a memory die can include multiple arrays that can be individually accessed.

Column control circuitry 216 receives a group of N column address signals and one or more various control signals from system control logic 208, and typically may include such circuits as column decoders 222, array terminal receivers or driver circuits 224, block select circuitry 226, as well as read/write circuitry, and I/O multiplexers.

System control logic 208 receives data and commands from memory controller 104 (FIG. 1) and provides output data and status to host 102. In some embodiments, system control logic 208 (which includes one or more electrical circuits) includes a state machine 228 that provides die-level control of memory operations.

In an embodiment, state machine 228 is programmable by software. In other embodiments, state machine 228 does not use software and is completely implemented in hardware (e.g., electrical circuits). In another embodiment, state machine 228 is replaced by a micro-controller or microprocessor, either on or off the memory chip.

System control logic 208 also can include a power control module 230 that controls the power and voltages supplied to the rows and columns of memory array 202 during memory operations and may include charge pumps and regulator circuit for creating regulating voltages. System control logic 208 includes storage 232 (e.g., RAM, registers, latches, etc.), which may be used to store parameters for operating memory array 202.

Commands and data are transferred between memory controller 104 and memory die 200 via memory controller interface 234 (also referred to as a “communication interface”). Memory controller interface 234 is an electrical interface for communicating with memory controller 104. Examples of memory controller interface 234 include a Toggle Mode Interface and an Open NAND Flash Interface (ONFI). Other I/O interfaces can also be used.

In some embodiments, all elements of memory die 200, including the system control logic 208, can be formed as part of a single die. In other embodiments, some or all of the system control logic 208 can be formed on a different die.

In an embodiment, memory array 202 comprises a three-dimensional memory array of non-volatile memory cells in which multiple memory levels are formed above a single substrate, such as a wafer. Memory array 202 may include any type of non-volatile memory that are monolithically formed in one or more physical levels of memory cells having an active area disposed above a silicon (or other type of) substrate. In an example, the non-volatile memory cells comprise vertical NAND strings with charge-trapping layers.

In another embodiment, memory array 202 includes a two-dimensional memory array of non-volatile memory cells. In an example, the non-volatile memory cells are NAND flash memory cells utilizing floating gates. Other types of memory cells (e.g., NOR-type flash memory) also can be used.

The exact type of memory array architecture or memory cell included in memory array 202 is not limited to the examples above. Many different types of memory array architectures or memory technologies can be used to form memory array 202. No particular non-volatile memory technology is required for purposes of the new claimed embodiments proposed herein.

Other examples of suitable technologies for memory cells of memory array 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of memory array 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell.

A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells.

In an embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light.

In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory array, memory construction or material composition, but covers many relevant memory array structures within the spirit and scope of the technology as described herein and as understood by one of ordinary skill in the art.

The elements of FIG. 2A can be grouped into two parts: (1) memory array 202 and (2) peripheral circuitry, which includes all of the other components depicted in FIG. 2A. An important characteristic of a memory circuit is its capacity, which can be increased by increasing the area of the memory die of storage system 100 that is given over to memory array 202. However, this reduces the area of the memory die available for the peripheral circuitry. This can place quite severe restrictions on these elements of the peripheral circuitry.

For example, the need to fit sense amplifier circuits within the available area can be a significant restriction on sense amplifier design architectures. With respect to system control logic 208, reduced availability of area can limit the available functions that can be implemented on-chip. Consequently, a basic trade-off in the design of a memory die for storage system 100 is the amount of area to devote to memory array 202 and the amount of area to devote to the peripheral circuitry.

Another area in which memory array 202 and the peripheral circuitry are often at odds is in the processing involved in forming these regions, since these regions often involve differing processing technologies and the trade-off in having differing technologies on a single die. For example, when memory array 202 is NAND flash, this is an NMOS structure, while the peripheral circuitry is often CMOS based.

For example, elements such as sense amplifier circuits, charge pumps, logic elements in a state machine, and other peripheral circuitry in system control logic 208 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed die that are then bonded together. More specifically, memory array 202 can be formed on one die (referred to as the memory die) and some or all of the peripheral circuitry elements, including one or more control circuits, can be formed on a separate die (referred to as the control die).

For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array.

The two die can then be bonded together in a bonded multi-die memory circuit, with the array on one die connected to the periphery elements on the other die. Although the following will focus on a bonded memory circuit of one memory die and one control die, other embodiments can use more die, such as two memory die and one control die, for example.

FIG. 2B is a simplified block diagram depicting portions of memory die 200 of FIG. 2A coupled to memory controller 104 of FIG. 1. In particular, memory die 200 includes an I/O buffer 236 disposed between memory controller interface 234 and sense amps 218, which are coupled to memory array 202. In embodiments, I/O buffer 236 may be coupled to memory controller interface 234 as depicted in FIG. 2B or may be included in memory controller interface 234.

In an embodiment, I/O buffer 236 includes data latches 238 (also referred to herein as “transfer data latches 238” or “XDL 238”. In an embodiment, transfer data latches 238 are used to store data being written to and read from memory array 202. In particular, data received from memory controller 104 at memory controller interface 234 for writing to memory array 202 in accordance with a write command are latched in transfer data latches 238 before being written to memory array 202. Similarly, data read from memory array 202 in accordance with a read command are latched in transfer data latches 238 before being transmitted via memory controller interface 234 to memory controller 104.

In an embodiment, sense amps 218 are used to read or program in parallel one or more pages of data in multiple memory cells of memory array 202. In an embodiment, each sense amp 218 is connected to a corresponding bit line in memory array 202.

In an embodiment, during read operations sense amps 218 sense voltages on each bit line and amplify the sensed voltages to conventional logic levels. In an embodiment, after a sense amp 218 for a particular bit line amplifies the sensed voltage to a conventional logic level, the bit from the desired cell is then latched from the sense amp 218 into a transfer data latches 238 in I/O buffer 236, and then transferred via memory controller interface 234 to memory controller 104.

In an embodiment, during write operations bit line drivers in sense amps 218 apply voltages to corresponding bit lines in memory array 202 in accordance with write data received via memory controller interface 234 from memory controller 104 and stored in transfer data latches 238.

FIG. 2C shows an alternative arrangement to that of FIG. 2A which may be implemented using wafer-to-wafer bonding to provide a bonded die pair. FIG. 2C depicts a functional block diagram of an embodiment of an integrated memory assembly 240. One or more integrated memory assemblies 240 may be used to implement non-volatile memory 106 of storage system 100.

Integrated memory assembly 240 includes two types of semiconductor die (or more succinctly, “die”). Memory die 242 includes memory array 202 that includes non-volatile memory cells. Control die 244 includes row control circuitry 204, system control logic 208, and column control circuitry 216 (as described above). In some embodiments, control die 244 is configured to connect to memory array 202 in memory die 242. In some embodiments, memory die 242 and control die 244 are bonded together.

FIG. 2C shows an example of the peripheral circuitry, including control circuits, formed in a peripheral circuit or control die 244 coupled to memory array 202 formed in memory die 242. Common components are labelled similarly to FIG. 2A. System control logic 208, row control circuitry 204, and column control circuitry 216 are located in control die 244. In some embodiments, all or a portion of column control circuitry 216 and all or a portion of row control circuitry 204 are located on memory die 242. In some embodiments, some of the circuitry in system control logic 208 is located on memory die 242.

Row control circuitry 204, system control logic 208, and column control circuitry 216 may be formed by a common process (e.g., CMOS process), so that adding elements and functions, such as ECC, more typically found on a memory controller 104 may require few or no additional process steps (i.e., the same process steps used to fabricate controller 104 also may be used to fabricate row control circuitry 204, system control logic 208, and column control circuitry 216).

Thus, while moving such circuits from a die such as memory 242 may reduce the number of steps needed to fabricate such a die, adding such circuits to a die such as control die 244 may not require many additional process steps. Control die 244 also could be referred to as a CMOS die, due to the use of CMOS technology to implement some or all of row control circuitry 204, system control logic 208, and column control circuitry 216.

FIG. 2C shows column control circuitry 216 including sense amplifier(s) 218 on control die 244 coupled to memory array 202 on memory die 242 through electrical paths 220. For example, electrical paths 220 may provide electrical connection between column decoder 222, driver circuitry 224, and block select 226 and bit lines of memory array 202.

Electrical paths may extend from column control circuitry 216 in control die 244 through pads on control die 244 that are bonded to corresponding pads of the memory die 242, which are connected to bit lines of memory array 202. Each bit line of memory array 202 may have a corresponding electrical path 220, including a pair of bond pads, which connects to column control circuitry 216.

Similarly, row control circuitry 204, including row decoder 210, array drivers 212, and block select 214 are coupled to memory array 202 through electrical paths 206. Each electrical path 206 may correspond to a word line, dummy word line, or select gate line. Additional electrical paths also may be provided between control die 244 and memory die 242.

For purposes of this document, the phrases “a control circuit” or “one or more control circuits” can include any one of or any combination of memory controller 104, state machine 228, all or a portion of row control circuitry 204, all or a portion of system control logic 208, all or a portion of column control circuitry 216, a microcontroller, a microprocessor, and/or other similar functioned circuits.

A control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In some embodiments, there is more than one control die 244 and more than one memory die 242 in an integrated memory assembly 240. In some embodiments, integrated memory assembly 240 includes a stack of multiple control die 244 and multiple memory die 242.

FIG. 2D is a simplified block diagram depicting portions of memory die 242 and control die 244 of FIG. 2C coupled to memory controller 104 of FIG. 1. In particular, control die 244 includes I/O buffer 236 disposed between memory controller interface 234 and sense amps 218, which are coupled to memory array 202 on memory die 242. In embodiments, I/O buffer 236 may be coupled to memory controller interface 234 as depicted in FIG. 2D or may be included in memory controller interface 234.

In an embodiment, I/O buffer 236 includes transfer data latches 238 that are used to store data being written to and read from memory array 202. In particular, data received from memory controller 104 at memory controller interface 234 for writing to memory array 202 in accordance with a write command are latched in transfer data latches 238 before being written to memory array 202. Similarly, data read from memory array 202 in accordance with a read command are latched in transfer data latches 238 before being transmitted via memory controller interface 234 to memory controller 104.

In an embodiment, sense amps 218 are used to read or program in parallel one or more pages of data in multiple memory cells of memory array 202. In an embodiment, each sense amp 218 is connected to a corresponding bit line in memory array 202.

In an embodiment, during read operations sense amps 218 sense voltages on each bit line and amplify the sensed voltages to conventional logic levels. In an embodiment, after a sense amp 218 for a particular bit line amplifies the sensed voltage to a conventional logic level, the bit from the desired cell is then latched from the sense amp 218 into a transfer data latches 238 in I/O buffer 236, and then transferred via memory controller interface 234 to memory controller 104.

In an embodiment, during write operations bit line drivers in sense amps 218 apply voltages to corresponding bit lines in memory array 202 in accordance with write data received via memory controller interface 234 from memory controller 104 and stored in transfer data latches 238.

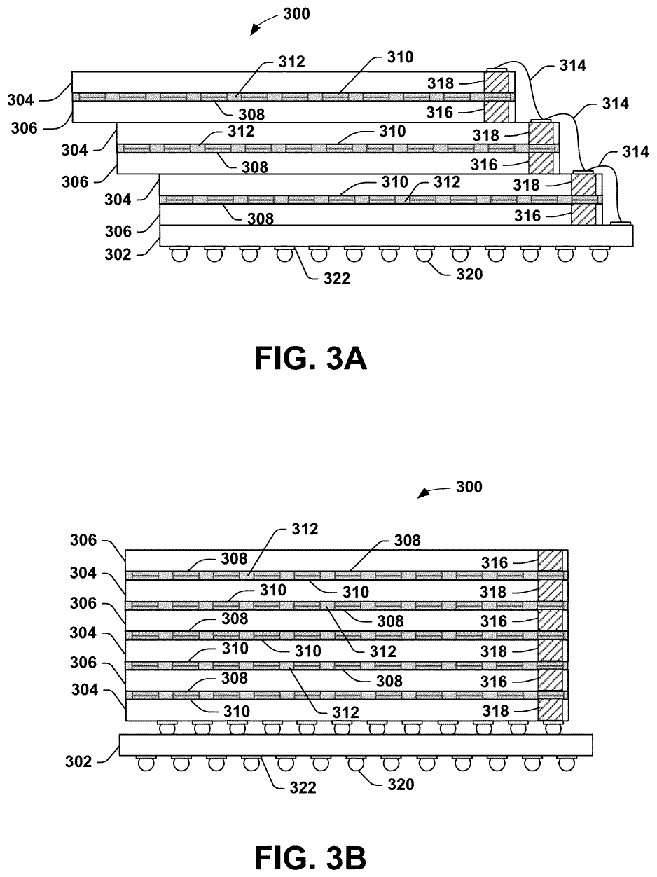

FIG. 3A depicts a side view of an embodiment of an integrated memory assembly 300 stacked on a substrate 302 (e.g., a stack including control die 304 and memory die 306). Integrated memory assembly 300 has three control die 304 and three memory die 306. In some embodiments, there are more than three memory die 306 and more than three control die 304.

Each control die 304 is affixed (e.g., bonded) to at least one memory die 306. Some bond pads 308/310 are depicted, although there may be many more bond pads. A space between two die 306, 304 that are bonded together is filled with a solid layer 312, which may be formed from epoxy or other resin or polymer. Solid layer 312 protects the electrical connections between die 304, 306, and further secures the die together. Various materials may be used as solid layer 312, but in embodiments, solid layer 312 may be Hysol epoxy resin from Henkel Corp., having offices in California, USA.

Integrated memory assembly 300 may for example be stacked with a stepped offset, leaving the bond pads at each level uncovered and accessible from above. Wire bonds 314 connected to the bond pads connect control die 304 to substrate 302. A number of such wire bonds may be formed across the width of each control die 304 (i.e., into the page of FIG. 3A).

A memory die through silicon via (TSV) 316 may be used to route signals through each memory die 306. A control die TSV 318 may be used to route signals through each control die 304. TSVs 316, 318 may be formed before, during or after formation of the integrated circuits in semiconductor die 306, 304. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 320 optionally may be affixed to contact pads 322 on a lower surface of substrate 302. Solder balls 320 may be used to couple integrated memory assembly 300 electrically and mechanically to a host device such as a printed circuit board. Solder balls 320 may be omitted where integrated memory assembly 300 is to be used as a land grid array package. Solder balls 320 may form a part of an interface between integrated memory assembly 300 and memory controller 104 (FIG. 1).

FIG. 3B depicts a side view of another embodiment of an integrated memory assembly 300 stacked on a substrate 302. Integrated memory assembly 300 of FIG. 3B has three control die 304 and three memory die 306. In some embodiments, there are many more than three memory die 306 and many more than three control die 304. In this example, each control die 304 is bonded to at least one memory die 306. Optionally, a control die 304 may be bonded to two or more memory die 306.

Some bond pads 308, 310 are depicted. There may be many more bond pads. A space between two die 306, 304 that are bonded together is filled with a solid layer 312, which may be formed from epoxy or other resin or polymer. In contrast to the example in FIG. 3A, integrated memory assembly 300 of FIG. 3B does not have a stepped offset. A memory die TSV 316 may be used to route signals through each memory die 306. A control die TSV 318 may be used to route signals through each control die 304.

As has been briefly discussed above, control die 304 and memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process.

In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension.

Such bonds may be formed at room temperature, though heat also may be applied. In embodiments using cu-to-cu bonding, the bond pads may be about 5 μm square and spaced from each other with a pitch of 5 μm to 5 μm. Although this process is referred to herein as cu-to-cu bonding, this term also may apply even where the bond pads are formed of materials other than copper.

When the area of bond pads is small, it may be difficult to bond the semiconductor die together. The size of and pitch between bond pads may be further reduced by providing a film layer on the surfaces of the semiconductor die including the bond pads. The film layer is provided around the bond pads. When the die are brought together, the bond pads may bond to each other, and the film layers on the respective die may bond to each other.

Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on surface of control die 304 and memory die 306. Where no such film is initially provided, a space between the die may be under filled with an epoxy or other resin or polymer. The under-fill material may be applied as a liquid which then hardens into a solid layer. This under-fill step protects the electrical connections between control die 304 and memory die 306, and further secures the die together. Various materials may be used as under-fill material, such as Hysol epoxy resin from Henkel Corp., having offices in California, USA.

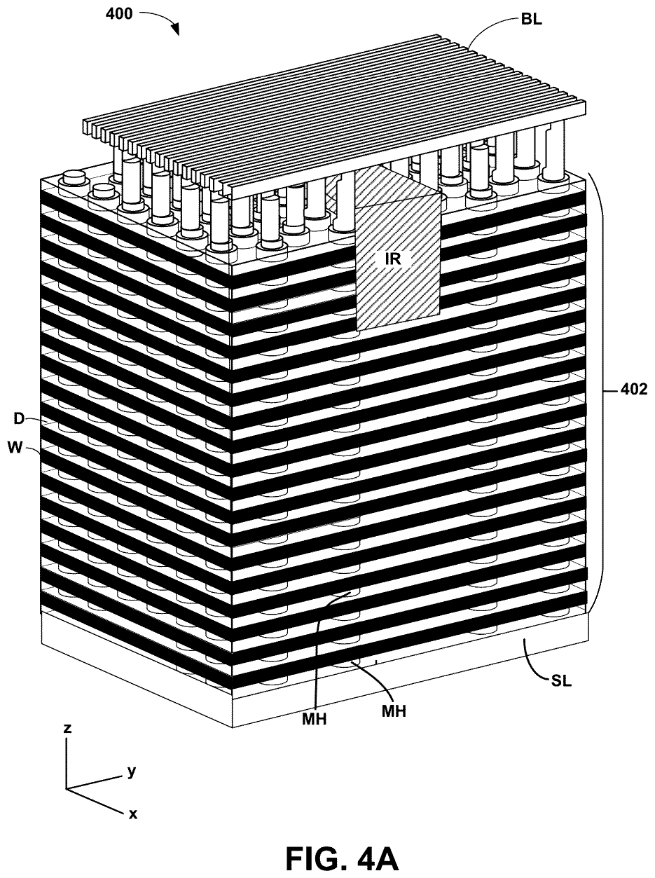

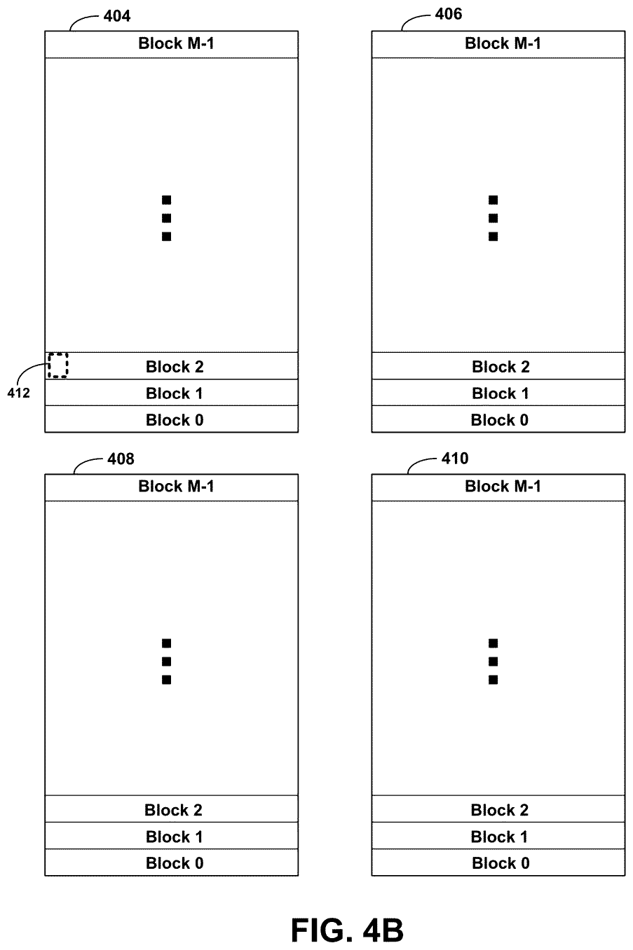

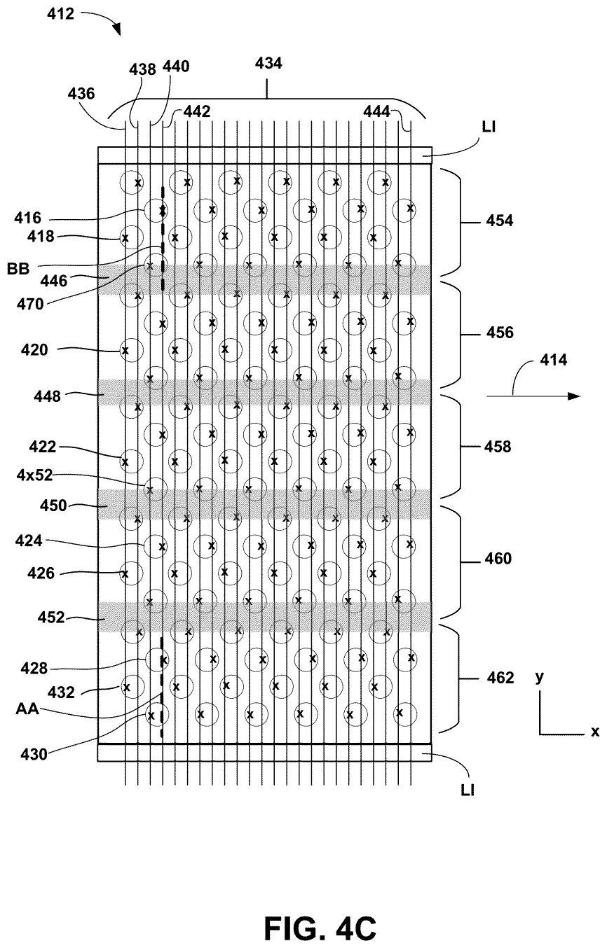

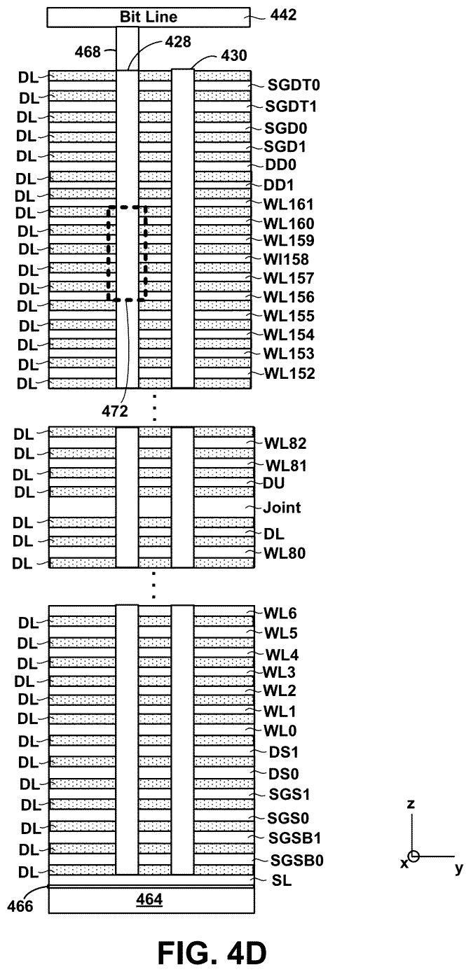

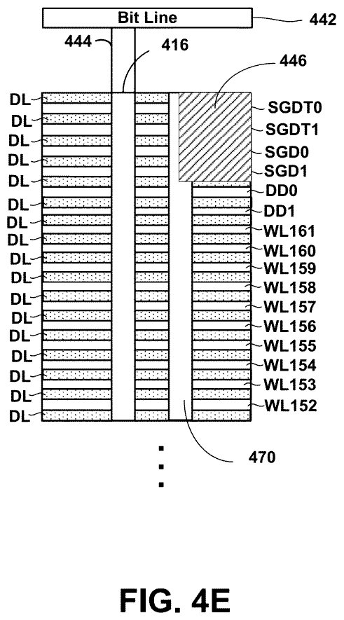

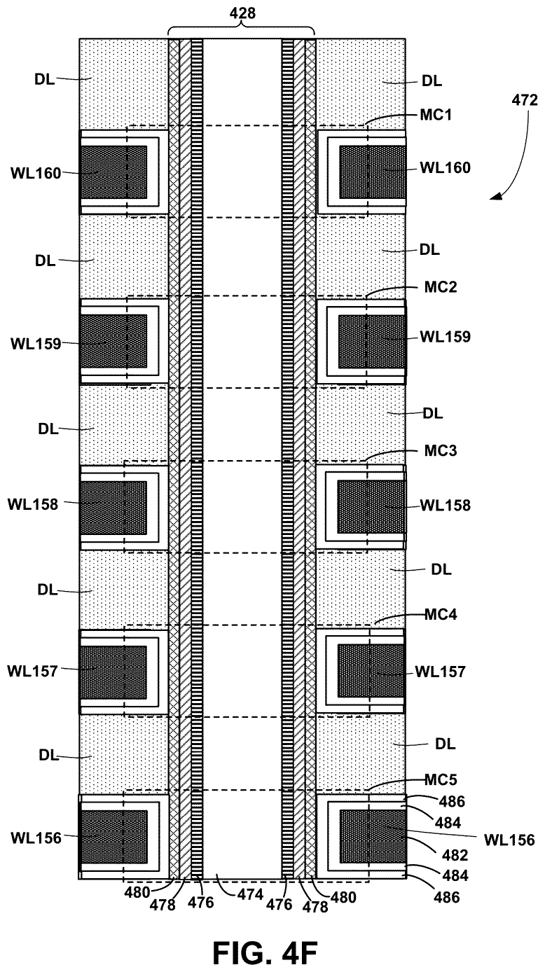

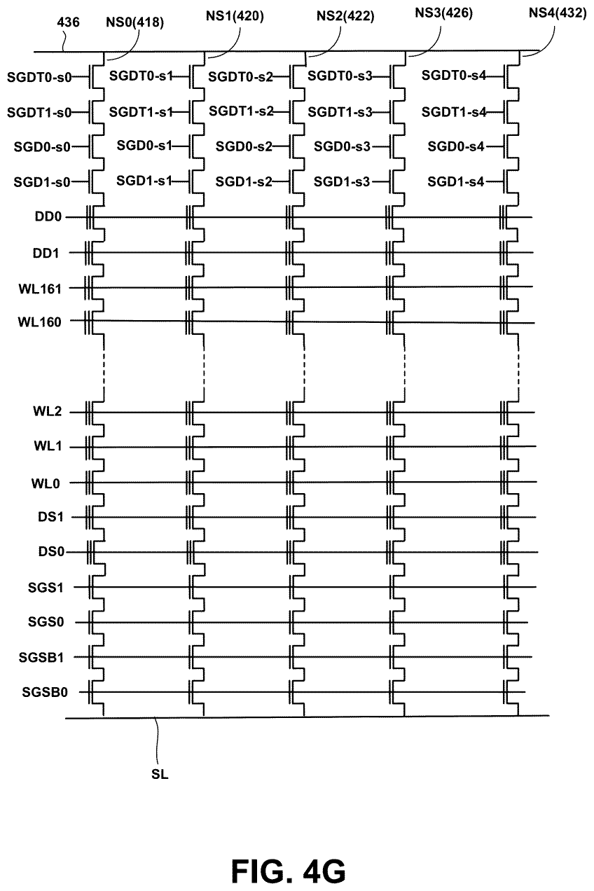

FIG. 4A is a perspective view of a portion of one example embodiment of a monolithic three dimensional memory array/structure included in memory array 202, which includes a plurality non-volatile memory cells arranged as vertical NAND strings. For example, FIG. 4A shows a portion 400 of one block of memory.

The structure depicted includes a set of bit lines BL positioned above a stack 402 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements.

As will be explained below, in an embodiment the alternating dielectric layers and conductive layers are divided into four or five (or a different number of) regions by isolation regions IR. FIG. 4A shows one isolation region IR separating two regions. Below the alternating dielectric layers and word line layers is a source line layer SL. Memory holes are formed in the stack of alternating dielectric layers and conductive layers.

For example, one of the memory holes is marked as MH. Note that in FIG. 4A, the dielectric layers are depicted as see-through so that the reader can see the memory holes positioned in the stack of alternating dielectric layers and conductive layers. In an embodiment, NAND strings are formed by filling the memory hole with materials including a charge-trapping material to create a vertical column of memory cells.

Each memory cell can store one or more bits of data. Thus, the non-volatile memory cells are arranged in memory holes. More details of the three dimensional monolithic memory array that comprises memory array 202 is provided below.

FIG. 4B is a block diagram explaining one example organization of memory array 202, which is divided into four planes 404, 406, 408 and 410. Each plane is then divided into M blocks. In an example, each plane has about 2000 blocks. However, different numbers of blocks and planes can also be used.

In an embodiment, a block of memory cells is a unit of erase. That is, all memory cells of a block are erased together. In other embodiments, blocks can be divided into sub-blocks and the sub-blocks can be the unit of erase. Memory cells also can be grouped into blocks for other reasons, such as to organize the memory array to enable the signaling and selection circuits.

In some embodiments, a block represents a groups of connected memory cells as the memory cells of a block share a common set of word lines. For example, the word lines for a block are all connected to all of the vertical NAND strings for that block. Although FIG. 4B shows four planes, more or less than four planes can be implemented. In some embodiments, memory array 202 includes eight planes.

Each block typically is divided into one or more pages. In an embodiment, a page is a unit of programming/writing and a unit of reading. Other units of programming also can be used. In an embodiment, one or more pages of data are typically stored in one row of memory cells. For example, one or more pages of data may be stored in memory cells connected to a common word line. In an embodiment, a page includes data stored in all memory cells connected to a common word line.

FIGS. 4C-4G depict an example three dimensional (“3D”) NAND structure that corresponds to the structure of FIG. 4A and can be used to implement memory array 202 of FIGS. 2A and 2C. FIG. 4C is a block diagram depicting a top view of a portion 412 of Block 2 of plane 404. As can be seen from FIG. 4C, the block depicted in FIG. 4C extends in the direction of 414. In an embodiment, the memory array has many layers. However, FIG. 4C only shows the top layer.

FIG. 4C depicts a plurality of circles that represent the memory holes, which are also referred to as vertical columns. Each of the memory holes/vertical columns include multiple select transistors (also referred to as a select gate or selection gate) and multiple memory cells. In an embodiment, each memory hole/vertical column implements a NAND string. For example, FIG. 4C labels a subset of the memory holes/vertical columns/NAND strings 416, 418, 420, 422, 424, 426, 428, 430 and 432.

FIG. 4C also depicts a set of bit lines 434, including bit lines 436, 438, 440, 442, . . . 444. FIG. 4C shows twenty four bit lines because only a portion of the block is depicted. It is contemplated that more than twenty four bit lines connected to memory holes/vertical columns of the block. Each of the circles representing memory holes/vertical columns has an “x” to indicate its connection to one bit line. For example, bit line 436 is connected to memory holes/vertical columns 418, 420, 422, 426 and 432.

The block depicted in FIG. 4C includes a set of isolation regions 446, 448, 450 and 452, which are formed of SiO₂. However, other dielectric materials also can be used. Isolation regions 446, 448, 450 and 452 serve to divide the top layers of the block into five regions For example, the top layer depicted in FIG. 4C is divided into regions 454, 456, 458, 460 and 462.

In an embodiment, the isolation regions only divide the layers used to implement select gates so that NAND strings in different regions can be independently selected. In an example implementation, a bit line connects to one memory hole/vertical column/NAND string in each of regions 454, 456, 458, 460 and 462. In that implementation, each block has twenty four rows of active columns and each bit line connects to five rows in each block.

In an embodiment, all of the five memory holes/vertical columns/NAND strings connected to a common bit line are connected to the same set of word lines; therefore, the system uses the drain side selection lines to choose one (or another subset) of the five to be subjected to a memory operation (program, verify, read, and/or erase).

FIG. 4C also shows Line Interconnects LI, which are metal connections to the source line SL from above the memory array. Line Interconnects LI are positioned adjacent regions 454 and 462.

Although FIG. 4C shows each region 454, 456, 458, 460 and 462 having four rows of memory holes/vertical columns, five regions and twenty four rows of memory holes/vertical columns in a block, those exact numbers are an example implementation. Other embodiments may include more or less regions per block, more or less rows of memory holes/vertical columns per region and more or less rows of vertical columns per block.

FIG. 4C also shows the memory holes/vertical columns being staggered. In other embodiments, different patterns of staggering can be used. In some embodiments, the memory holes/vertical columns are not staggered.

FIG. 4D depicts a portion of one embodiment of a three dimensional memory array 202 showing a cross-sectional view along line AA of FIG. 4C. This cross sectional view cuts through memory holes/vertical columns (NAND strings) 428 and 430 of region 462 (see FIG. 4C).

The structure of FIG. 4D includes two drain side select layers SGD0 and SGD, the source side select layers SGS0 and SGS1, two drain side GIDL generation transistor layers SGDT0 and SGDT1, two source side GIDL generation transistor layers SGSB0 and SGSB1, two drain side dummy word line layers DD0 and DD1, two source side dummy word line layers DS0 and DS1, dummy word line layers DU and DL, one hundred and sixty two word line layers WL0-WL161 for connecting to data memory cells, and dielectric layers DL.

Other embodiments can implement more or less than the numbers described above for FIG. 4D. In an embodiment, SGD0 and SGD1 are connected together; and SGS0 and SGS1 are connected together. In other embodiments, more or less number of SGDs (greater or lesser than two) are connected together, and more or less number of SGS devices (greater or lesser than two) connected together.

In an embodiment, erasing the memory cells is performed using gate induced drain leakage (GIDL), which includes generating charge carriers at the GIDL generation transistors such that the carriers get injected into the charge trapping layers of the NAND strings to change threshold voltage of the memory cells. FIG. 4D shows two GIDL generation transistors at each end of the NAND string; however, in other embodiments there are more or less than three.

Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

FIG. 4D shows two GIDL generation transistors at each end of the NAND string. It is likely that charge carriers are only generated by GIDL at one of the two GIDL generation transistors at each end of the NAND string. Based on process variances during manufacturing, it is likely that one of the two GIDL generation transistors at an end of the NAND string is best suited for GIDL.

For example, the GIDL generation transistors have an abrupt PN junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

Memory holes/Vertical columns 428 and 430 are depicted protruding through the drain side select layers, source side select layers, dummy word line layers, GIDL generation transistor layers and word line layers. In an embodiment, each memory hole/vertical column comprises a vertical NAND string. Below the memory holes/vertical columns and the layers listed below is substrate 464, an insulating film 466 on the substrate, and source line SL. The NAND string of memory hole/vertical column 428 has a source end at a bottom of the stack and a drain end at a top of the stack. As in agreement with FIG. 4C, FIG. 4D show vertical memory hole/column 428 connected to bit line 442 via connector 468.

For ease of reference, drain side select layers, source side select layers, dummy word line layers, GIDL generation transistor layers and data word line layers collectively are referred to as conductive layers.

In an embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof.

In some embodiments, different conductive layers can be formed from different materials. Between conductive layers are dielectric layers DL. In an embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In an embodiment, the memory cells are arranged in NAND strings. The word line layers WL0-W161 connect to memory cells (also called data memory cells). Dummy word line layers connect to dummy memory cells.

A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD0 and SGD1 are used to electrically connect and disconnect NAND strings from bit lines. Source side select layers SGS0 and SGS1 are used to electrically connect and disconnect NAND strings from the source line SL.

FIG. 4D shows that the memory array is implemented as a two tier architecture, with the tiers separated by a Joint area. In an embodiment it is expensive and/or challenging to etch so many word line layers intermixed with dielectric layers. To ease this burden, one embodiment includes laying down a first stack of word line layers (e.g., WL0-WL80) alternating with dielectric layers, laying down the Joint area, and laying down a second stack of word line layers (e.g., WL81-WL161) alternating with dielectric layers. The Joint area are positioned between the first stack and the second stack. In an embodiment, the Joint areas are made from the same materials as the word line layers. In other embodiments, there can no Joint area or there can be multiple Joint areas.

FIG. 4E depicts a portion of one embodiment of a three dimensional memory array 202 showing a cross-sectional view along line BB of FIG. 4C. This cross sectional view cuts through memory holes/vertical columns (NAND strings) 416 and 470 of region 454 (see FIG. 4C). FIG. 4E shows the same alternating conductive and dielectric layers as FIG. 4D.

FIG. 4E also shows isolation region 446. Isolation regions 446, 448, 450 and 452) occupy space that would have been used for a portion of the memory holes/vertical columns/NAND stings. For example, isolation region 446 occupies space that would have been used for a portion of memory hole/vertical column 470. More specifically, a portion (e.g., half the diameter) of vertical column 470 has been removed in layers SGDT0, SGDT1, SGD0, and SGD1 to accommodate isolation region 446.

Thus, while most of the vertical column 470 is cylindrical (with a circular cross section), the portion of vertical column 470 in layers SGDT0, SGDT1, SGD0, and SGD1 has a semi-circular cross section. In an embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 454, 456, 458, 460, and 462.

FIG. 4F depicts a cross sectional view of region 472 of FIG. 4D that includes a portion of memory hole/vertical column 428. In an embodiment, the memory holes/vertical columns are round. However, in other embodiments other shapes can be used. In an embodiment, memory hole/vertical column 428 includes an inner core layer 474 that is made of a dielectric, such as SiO₂. Other materials can also be used.

Surrounding inner core 474 is polysilicon channel 476. Materials other than polysilicon can also be used. Note that it is the channel 476 that connects to the bit line and the source line. Surrounding channel 476 is a tunneling dielectric 478. In an embodiment, tunneling dielectric 478 has an ONO structure. Surrounding tunneling dielectric 478 is charge trapping layer 480, such as (for example) Silicon Nitride. Other memory materials and structures can also be used. The technology described herein is not limited to any particular material or structure.

FIG. 4F depicts dielectric layers DL as well as word line layers WL160, WL159, WL158, WL157, and WL156. Each of the word line layers includes a word line region 482 surrounded by an aluminum oxide layer 484, which is surrounded by a blocking oxide layer 486. In other embodiments, the blocking oxide layer can be a vertical layer parallel and adjacent to charge trapping layer 480. The physical interaction of the word line layers with the vertical column forms the memory cells.

Thus, in an embodiment a memory cell includes channel 476, tunneling dielectric 478, charge trapping layer 480, blocking oxide layer 486, aluminum oxide layer 484 and word line region 482. For example, word line layer WL160 and a portion of memory hole/vertical column 428 comprise a memory cell MC1. Word line layer WL159 and a portion of memory hole/vertical column 428 comprise a memory cell MC2. Word line layer WL158 and a portion of memory hole/vertical column 428 comprise a memory cell MC3. Word line layer WL157 and a portion of memory hole/vertical column 428 comprise a memory cell MC4. Word line layer WL156 and a portion of memory hole/vertical column 428 comprise a memory cell MC5. In other architectures, a memory cell may have a different structure; however, the memory cell would still be the storage unit.

When a memory cell is programmed, electrons are stored in a portion of the charge trapping layer 480 which is associated with (e.g. in) the memory cell. These electrons are drawn into the charge trapping layer 480 from the channel 476, through the tunneling dielectric 478, in response to an appropriate voltage on word line region 482. The threshold voltage (Vth) of a memory cell is increased in proportion to the amount of stored charge.

In an embodiment, the programming is achieved through Fowler-Nordheim tunneling of the electrons into the charge trapping layer. During an erase operation, the electrons return to the channel or holes are injected into the charge trapping layer to recombine with electrons. In an embodiment, erasing is achieved using hole injection into the charge trapping layer via a physical mechanism such as GIDL.

FIG. 4G is a schematic diagram of a portion of the three dimensional memory array 202 depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in an embodiment, each bit line is connected to five NAND strings, one in each region of regions 454, 456, 458, 460, 462.

Thus, FIG. 4G shows bit line 436 connected to NAND string NS0 (which corresponds to memory hole/vertical column 418 of region 454), NAND string NS1 (which corresponds to memory hole/vertical column 420 of region 456), NAND string NS2 (which corresponds to vertical column 422 of region 458), NAND string NS3 (which corresponds to memory hole/vertical column 426 of region 460), and NAND string NS4 (which corresponds to memory hole/vertical column 432 of region 462).

Drain side select line/layer SGD0 is separated by isolation regions isolation regions 446, 448, 450 and 452 to form SGD0-s0, SGD0-s1, SGD0-s2, SGD0-s3 and SGD0-s4 in order to separately connect to and independently control regions 454, 456, 458, 460, 462.

Similarly, drain side select line/layer SGD1 is separated by isolation regions 446, 448, 450 and 452 to form SGD1-s0, SGD1-s1, SGD1-s2, SGD1-s3 and SGD1-s4 in order to separately connect to and independently control regions 454, 456, 458, 460, 462.

Drain side GIDL generation transistor control line/layer SGDT0 is separated by isolation regions 446, 448, 450 and 452 to form SGDT0-s0, SGDT0-s1, SGDT0-s2, SGDT0-s3 and SGDT0-s4 in order to separately connect to and independently control regions 454, 456, 458, 460, 462.

Drain side GIDL generation transistor control line/layer SGDT1 is separated by isolation regions 446, 448, 450 and 452 to form SGDT1-s0, SGDT1-s1, SGDT1-s2, SGDT1-s3 and SGDT1-s4 in order to separately connect to and independently control regions 454, 456, 458, 460, 462.

FIG. 4G only shows NAND strings connected to bit line 436. However, a full schematic of the block would show every bit line and five vertical NAND strings (that are in separate regions) connected to each bit line.

Although the example memories of FIGS. 4B-4G are three dimensional memory arrays that include vertical NAND strings with charge-trapping material, other (2D and 3D) memory arrays can also be used with the technology described herein.

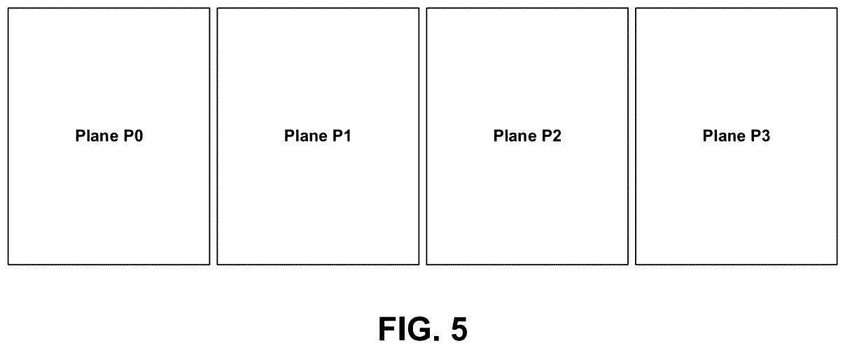

As described above, a memory array (such as memory array 202 of FIG. 2A) may include multiple planes, and each plane may operate in parallel. For example, FIG. 5 is a diagram depicting a memory array that includes four planes: P0, P1, P2 and P3. In an embodiment, each of planes P0, P1, P2 and P3 includes a physical page size. For example, the physical page size may be 4 kB/page. Other physical page sizes may be used.

As described above, HBM DRAM devices are being used for artificial intelligence/machine learning applications, but HBM has some disadvantages (e.g., cost, limited availability). HBF memory is significantly less expensive than DRAM, and may be used to replace HBM. HBF memory devices typically achieve higher bandwidth by stacking multiple NAND memory die in a package, with the multiple NAND memory die operating in parallel to achieve required bandwidth. Because the NAND memory die need to operate in parallel, achieving high throughput in each NAND memory die is very important.

Current NAND flash memory toggle mode input-output (“IO”) speed is sufficiently high to design the HBF memories. However, NAND memory die have large latencies such as the array programming time (tPRG) and array read time (tRD) which significantly reduce throughput.

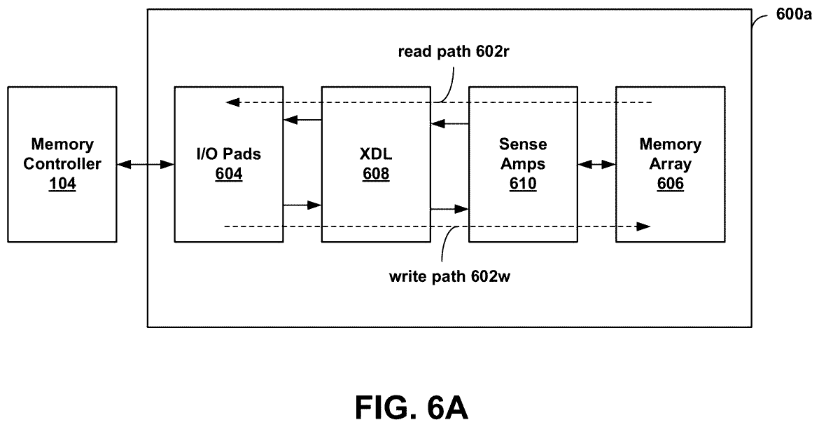

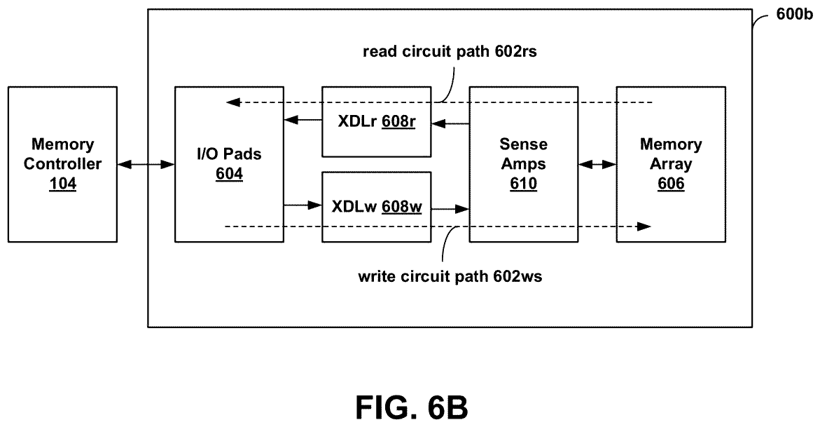

For example, FIG. 6A is a simplified block diagram depicting a portion 600a of memory die 200 of FIG. 2A. In particular, portion 600a is a simplified view of a write (programming) path 602w and a read path 602r between input-output (I/O) pads 604 and a memory array 606. In an embodiment, memory array 606 may be an implementation of memory array 202 of FIGS. 2A-2D.

In an embodiment, write path 602w and read path 602r share a single set of transfer data latches 608 and sense amps 610 disposed between I/O pads 604 and memory array 606. In embodiments, transfer data latches 608 may be an implementation of transfer data latches 238 of FIGS. 2B and 2D, and sense amps 610 may be an implementation of sense amps 218 of FIGS. 2A-2D. Persons of ordinary skill in the art will understand that portion 600a may include additional or different elements than those depicted in FIG. 6A.

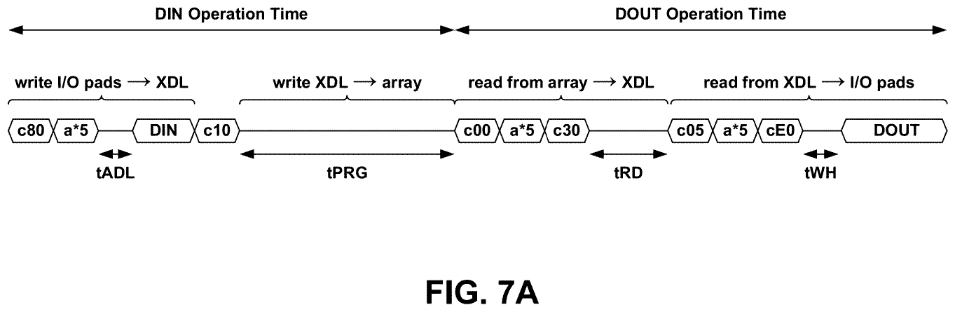

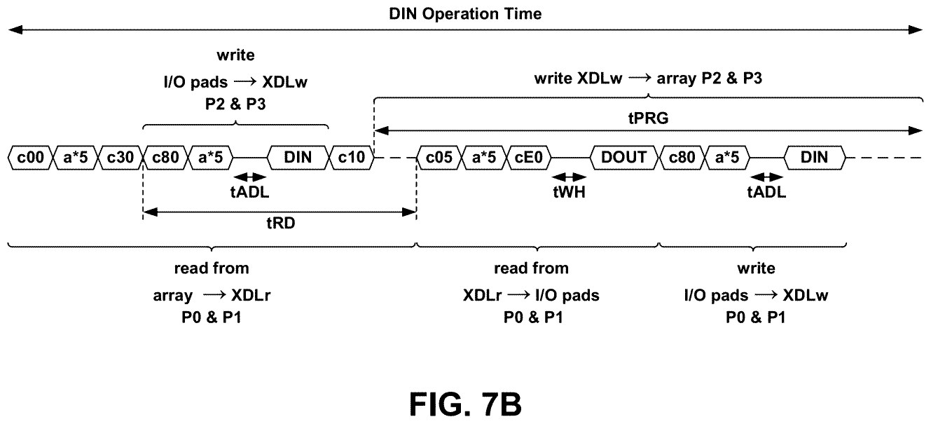

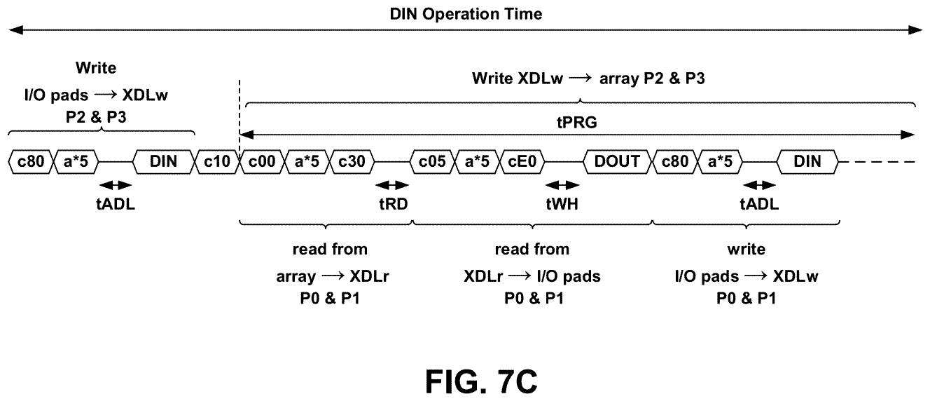

FIG. 7A is a simplified diagram of an example series of commands and addresses sent from a memory controller (e.g., memory controller 104 of FIG. 1) to memory die 200 including portion 600a of FIG. 6A. In particular, FIG. 7A depicts an example series of commands and addresses for a 4 KB data-in operation along write path 602w and a 4 KB data-out operation along read path 602r for memory array 606. Commands are depicted by the letter “c” followed by a two-digit hex number, and addresses are depicted by the symbol “a*5”, which represents a five byte address. In an embodiment, a command and address cycle time tWC=10 nsec. Persons of ordinary skill in the art will understand that other command and address cycle times may be used.

Also depicted in FIG. 7A are labels with the following meanings and example execution times, assuming single level cell (SLC) programming:

| Label | Meaning | Example Execution Time (nsec) |
|---|---|---|
| tADL | data-in wait time | 300 |
| tPRG | array programming time | 50,000 |
| tRD | array read time | 15,000 |
| tWH | data-out hold time | 300 |

In the example depicted in FIG. 7A, to write data from I/O Pads 604 to transfer data latches 608, memory controller 104 sends a first command (e.g., c80) and a five byte address (a*5) to memory die 200, waits a data-in wait time tADL, and then clocks in 4 KB data-in (DIN). In an embodiment, data-in wait time tADL=300 nsec, although other values may be used. In an example embodiment, a toggle mode speed tRC=0.416 nsec/byte, and thus the execution time to clock data-in (tDIN) for 4 KB DIN=4×1024×0.416=1,704 nsec. After this interval, memory controller 104 sends a second command (e.g., c10) to memory die 200, and then waits tPRG, the time required to write DIN from XDL 608 to memory array 606. As described above, an example tPRG=50,000 nsec, although other values may be used.

After completing the write operation along write path 602w, a read operation along read path 602r is performed. In the example depicted in FIG. 7A, to read data from memory array 606 to XDL 608, memory controller 104 sends a third command (e.g., c00), a five byte address (a*5), and a fourth command (e.g., c30) to memory die 200 and then waits an array read time tRD. As described above, an example array read time tRD=15,000 nsec, although other values may be used.

After array read time tRD, memory controller 104 sends a fifth command (e.g., c05), a five byte address (a*5), and a sixth command (e.g., cE0) to memory die 200, waits a data-out hold time tWH, and then clocks out 4 KB data-out (DOUT). In an embodiment, data-out hold time tWH=300 nsec, although other values may be used. In an example embodiment, with toggle mode speed tRC=0.416 nsec/byte, the execution time to clock data-out (tDOUT) for 4 KB DOUT=4×1024× 0.416=1,704 nsec.

Assuming that 2 planes are already written into memory array 606, the throughput of the example data-in/data-out operation depicted in FIG. 7A may be calculated as follows:

$$\begin{matrix}DIN Operation Time = ( 6 \times tWC ) + tADL + tDIN + tWC + tPRG \\ = 6 \times 10 + 300 + 1 , 704 + 10 + 50 , 000 \\ = 52 , 074 nsec\end{matrix}$$

$$DIN Time = 6 \times 10 + 1 , 704 + 10 = 1 , 774 nsec$$

$$\begin{matrix}DOUT Operation Time = ( 7 \times tWC ) + tRD + ( 7 \times tWC ) + t WH + tDOUT \\ = 7 \times 10 + 15 , 000 + 7 \times 10 + 300 + 1 , 704 \\ = 17 , 144 ns\end{matrix}$$

$$DOUT Time = 7 \times 10 + 7 \times 10 + 1 , 704 = 1 , 844 ns$$

where DIN Time equals the time for commands, addresses and time to clock data-in, and DOUT Time equals the time for commands, addresses and time to clock data-out.

In an embodiment, throughput may be calculated as:

$$\begin{matrix}Throughput = \frac{( DIN Time + DOUT Time )}{( DIN Operation Time + DOUT Operation Time )} \\ = \frac{( 1744 + 1844 )}{( 52074 + 17144 )} \\ = 5.2 \%\end{matrix}$$

In the example portion 600a of memory die 200 depicted in FIG. 6A, a single set of transfer data latches 608 are shared between write path 602w and read path 602r, and hence read and write operations to and from transfer data latches 608 cannot be performed in parallel. As a result, latencies cannot be hidden under high-speed data transfers and overall memory throughput is relatively low.

FIG. 6B is a simplified block diagram depicting a portion 600b of memory die 200 of FIG. 2A. In particular, portion 600b is a simplified view of a first circuit path 602ws and a second circuit path 602rs each disposed between input-output (I/O) pads 604 and a memory array 606.

In an embodiment, memory array 606 may be an implementation of memory array 202 of FIGS. 2A-2D. In an embodiment, first circuit path 602ws is a write (programming) circuit path 602ws and second circuit path 602rs is a read circuit path 602rs disposed between I/O pads 604 and memory array 606.

In an embodiment, write circuit path 602ws includes circuits configured to receive data from memory controller 104 and write (program) the received data in memory array 606. In an embodiment, read circuit path 602rs includes circuits configured to read data from memory array 606 and provide the read data to memory controller 104.

In an embodiment, write circuit path 602ws and read circuit path 602rs each include a corresponding set of transfer data latches. In an embodiment, write circuit path 602ws includes a corresponding first set of transfer data latches 608w, and read circuit path 602rs includes a corresponding second set of transfer data latches 608r. For simplicity, first set of transfer data latches 608w also is referred to herein as write transfer data latches 608w, and second set of transfer data latches 608r also is referred to herein as read transfer data latches 608r.

In an embodiment, write transfer data latches 608w and read transfer data latches 608r are not the same transfer data latches. In an embodiment, write transfer data latches 608w are different from read transfer data latches 608r. In an embodiment, write transfer data latches 608w are configured exclusively for a first type of memory operations, and read transfer data latches 608r are configured exclusively for a second type of memory operations. In an embodiment, write transfer data latches 608w are configured exclusively for program operations, and read transfer data latches 608r are configured exclusively for read operations.

In an embodiment, write circuit path 602ws includes corresponding write transfer data latches 608w disposed between I/O pads 604 and memory array 606. In an embodiment, write transfer data latches 608w are configured to receive data to be programmed in memory array 104. In an embodiment, write transfer data latches 608w are configured to receive from memory controller 104 data to be programmed in memory array 104. In an embodiment, write transfer data latches 608w are configured to provide the received data for programming in memory array 606. In an embodiment, write transfer data latches 608w are configured to provide the received data to sense amps 610 for programming in memory array 606.

In an embodiment, read circuit path 602rs includes corresponding read transfer data latches 608r disposed between I/O pads 604 and memory array 606. In an embodiment, read transfer data latches 608r are configured to receive data read from memory array 104. In an embodiment, read transfer data latches 608r are configured to receive from sense amps 610 data read from memory array 104. In an embodiment, read transfer data latches 608r are configured to provide the received data read from memory array 606. In an embodiment, read transfer data latches 608r are configured to provide memory controller 104 the received data read from memory array 606.

Thus, in contrast to portion 600a of FIG. 6A, which includes a single set of transfer data latches 608 shared by write path 602w and read path 602r, portion 600b includes separate write transfer data latches 608w and read transfer data latches 608r for write circuit path 602ws and read circuit path 602rs, respectively. In embodiments, each of write transfer data latches 608w and read transfer data latches 608r may be an implementation of transfer data latches 238 of FIGS. 2B and 2D. Persons of ordinary skill in the art will understand that portion 600b may include additional or different elements than those depicted in FIG. 6B.

FIG. 7B is a simplified diagram of a first example series of commands and addresses sent from a memory controller (e.g., memory controller 104 of FIG. 1) to memory die 200 including portion 600b of FIG. 6B. In particular, FIG. 7B depicts an example series of commands and addresses for a 4 KB data-out operation along read circuit path 602rs of FIG. 6B and a 4 KB data-in operation along write circuit path 602ws of FIG. 6B for memory array 606.

In the example depicted in FIG. 7B, assume that planes P0 and P1 of memory array 606 are already written with data and can be read in parallel with a programming operation for planes P2 and P3 of memory array 606. To read data along read circuit path 602rs from planes P0 and P1 of memory array 606 to read transfer data latches 608r, memory controller 104 sends a first command (e.g., c00), a five byte address (a*5), and a second command (e.g., c30) to memory die 200 and then waits an array read time tRD. In an embodiment, array read time tRD=15,000 nsec, although other values may be used.

During array read time tRD while data are read along read circuit path 602rs from planes P0 and P1 of memory array 606 to read transfer data latches 608r, data for planes P2 and P3 can be written along write circuit path 602ws from I/O Pads 604 to write transfer data latches 608w. In particular, memory controller 104 sends a third command (e.g., c80) and a five byte address (a*5) to memory die 200, waits a data-in wait time tADL, and then clocks in 4 KB DIN for planes P2 and P3 along write circuit path 602ws from I/O Pads 604 to write transfer data latches 608w. In an embodiment, data-in wait time tADL=300 nsec, although other values may be used.

As described above, in an example embodiment with a toggle mode speed (RC=0.416 nsec/byte and a 4 KB DIN, tDIN=1,704 nsec. After this interval, memory controller 104 sends a fourth command (e.g., c10) to memory die 200, and then waits tPRG, the time required to write DIN along write circuit path 602ws from write transfer data latches 608w to memory array 606 for planes P2 and P3. In an embodiment, an example tPRG=50,000 nsec.

In an embodiment, while DIN data are written along write circuit path 602ws from write transfer data latches 608w to memory array 606 for planes P2 and P3, data for planes P0 and P1 are read along read circuit path 602rs from read transfer data latches 608r to I/O Pads 604. In particular, after array read time tRD memory controller 104 sends a fifth command (e.g., c05), a five byte address (a*5), and a sixth command (e.g., cE0) to memory die 200, waits a data-out hold time tWH, and then clocks out 4 KB DOUT for planes P0 and P1 along read circuit path 602rs from read transfer data latches 608r to I/O Pads 604. In an embodiment, data-out hold time tWH=300 nsec, although other values may be used. As described above, in an example embodiment with a toggle mode speed tRC=0.416 nsec/byte and a 4 KB DOUT, tDOUT=1,704 nsec.

In an embodiment, after data for planes P0 and P1 are read along read circuit path 602rs from read transfer data latches 608r to I/O Pads 604, and while DIN data are written along write circuit path 602ws from write transfer data latches 608w to memory array 606 for planes P2 and P3, data for planes P0 and P1 can be written along write circuit path 602ws from I/O Pads 604 to write transfer data latches 608w. In particular, memory controller 104 sends a seventh command (e.g., c80) and a five byte address (a*5) to memory die 200, waits a data-in wait time tADL, and then clocks in 4 KB DIN for planes P0 and P1 to write transfer data latches 608w.

Thus, in the illustrated example, while plane P0 and P1 data are read along read circuit path 602rs from memory array 606 to read transfer data latches 608r, and then from read transfer data latches 608r to I/O Pads 604, plane P2 and P3 data are written along write circuit path 602ws from I/O Pads 604 to write transfer data latches 608w, and then from write transfer data latches 608w to memory array 606. The two operations are performed in parallel.

In an embodiment, the throughput of the example data-in/data-out operation depicted in FIG. 7B may be calculated as follows:

$$\begin{matrix}DIN Operation Time = ( 13 \times tWC ) + tADL + tDIN + tWC + tPRG \\ = 13 \times 10 + 300 + 1 , 704 + 10 + 50 , 000 \\ = 52 , 144 nsec\end{matrix}$$

$$\begin{matrix}TC \& D Time = ( 27 \times tWC ) + 2 \times tDIN + tDOUT \\ = 27 \times 10 + 3 \times 1 , 704 \\ = 5 , 382 ns\end{matrix}$$

where TC&D Time equals the time for commands, addresses and time to clock data-in, and clock data-out.

In an embodiment, throughput may be calculated as:

$$Throughput = \frac{T C \& D Time}{DIN Operation Time}$$

$$Throughput = \frac{5382}{52 , 144} = 10.3 \%$$

Thus, without wanting to be bound by any particular theory, it is believed that using the example embodiment of FIG. 6B including write circuit path 602ws and read circuit path 602rs that each include corresponding separate write transfer data latches 608w and read transfer data latches 608r, respectively, memory controller 104 may be able to perform array read and write operations in parallel for a single plane or multiple planes.

Without wanting to be bound by any particular theory, it is believed that including write circuit path 602ws and read circuit path 602rs that each include corresponding separate write transfer data latches 608w and read transfer data latches 608r may increase throughput. Indeed, in the example depicted in FIG. 7B it is believed that the throughput is almost twice the throughput of the example of FIG. 7A for a system that includes a single set of transfer data latches that is shared for read and write operations.

Without wanting to be bound by any particular theory, it is believed that including write circuit path 602ws and read circuit path 602rs that each include corresponding separate write transfer data latches 608w and read transfer data latches 608r may improve bus efficiency and memory bandwidth.

FIG. 7C is a simplified diagram of another example series of commands and addresses sent from a memory controller (e.g., memory controller 104 of FIG. 1) to memory die 200 including portion 600b of FIG. 6B. In particular, FIG. 7C depicts an example series of commands and addresses for a 4 KB data-in and a 4 KB data-out operation for memory array 606.

In the example depicted in FIG. 7C, assume that planes P0 and P1 of memory array 606 are already written with data and can be read in parallel with a programming operation for planes P2 and P3 of memory array 606.

To write data for planes P2 and P3 along write circuit path 602ws from I/O Pads 604 to write transfer data latches 608w, memory controller 104 sends a first command (e.g., c80) and a five byte address (a*5) to memory die 200, waits a data-in wait time tADL, and then clocks in 4 KB DIN for planes P2 and P3 along write circuit path 602ws from I/O Pads 604 to write transfer data latches 608w. In an embodiment, data-in wait time tADL=300 nsec, although other values may be used.

In an example embodiment, a toggle mode speed tRC=0.416 nsec/byte, and thus the execution time for 4 KB DIN=4×1024×0.416=1,704 nsec. After this interval, memory controller 104 sends a second command (e.g., c10) to memory die 200, and then waits tPRG, the time required to write DIN for planes P2 and P3 along write circuit path 602ws from write transfer data latches 608w to memory array 606. In an embodiment, an example tPRG=50,000 nsec.

In an embodiment, while DIN for planes P2 and P3 are written along write circuit path 602ws from write transfer data latches 608w to memory array 606, data for planes P0 and P1 are read along read circuit path 602rs from memory array 606 to read transfer data latches 608r. In particular, memory controller 104 sends a third command (e.g., c00), a five byte address (a*5), and a fourth command (e.g., c30) to memory die 200 and then waits an array read time tRD. In an embodiment, array read time tRD=15,000 nsec, although other values may be used.

In an embodiment, after array read time tRD memory controller 104 sends a fifth command (e.g., c05), a five byte address (a*5), and a sixth command (e.g., cE0) to memory die 200, waits a data-out hold time tWH, and then clocks out 4 KB DOUT for planes P0 and P1 along read circuit path 602rs from read transfer data latches 608r to I/O Pads 604. In an embodiment, data-out hold time tWH=300 nsec, although other values may be used. In an example embodiment, with toggle mode speed tRC=0.416 nsec/byte, the execution time for 4 KB DOUT=4×1024× 0.416=1,704 nsec.

In an embodiment, after data for planes P0 and P1 are read along read circuit path 602rs from read transfer data latches 608r to I/O Pads 604, and while DIN data for planes P2 and P3 are written along write path 602rs from write transfer data latches 608w to memory array 606, data for planes P0 and P1 can be written along write path 602rs from I/O Pads 604 to write transfer data latches 608w. In particular, memory controller 104 sends a seventh command (e.g., c80) and a five byte address (a*5) to memory die 200, waits a data-in wait time tADL, and then clocks in 4 KB DIN for planes P0 and P1 along write path 602rs from I/O Pads 604 to write transfer data latches 608w.

Thus, in the illustrated example, while plane P2 and P3 data are written along write path 602rs from write transfer data latches 608w to memory array 606, plane P0 and P1 data are read along read circuit path 602rs from memory array 606 to read transfer data latches 608r, and then from read transfer data latches 608r to I/O Pads 604. The two operations are performed in parallel.

In an embodiment, the throughput of the example data-in/data-out operation depicted in FIG. 7C may be calculated as follows:

$$\begin{matrix}DIN Operation Time = ( 6 \times tWC ) + tADL + tDIN + tWC + tPRG \\ = 6 \times 10 + 300 + 1 , 704 + 10 + 50 , 000 \\ = 52 , 074 nsec\end{matrix}$$

$$\begin{matrix}TC \& D Time = ( 27 \times tWC ) + 2 \times tDIN + tDOUT \\ = 27 \times 10 + 3 \times 1 , 704 \\ = 5 , 382 ns\end{matrix}$$

where TC&D Time equals the time for commands, addresses and time to clock data-in, and clock data-out.

In an embodiment, throughput may be calculated as:

$$Throughput = \frac{T C \& D Time}{DIN Operation Time}$$

$$Throughput = \frac{5382}{52 , 074} = 10.3 \%$$

Thus, without wanting to be bound by any particular theory, it is believed that using the example embodiment of FIG. 6B including write circuit path 602ws and read circuit path 602rs that each include corresponding separate write transfer data latches 608w and read transfer data latches 608r, respectively, memory controller 104 may be able to perform array read and write operations in parallel for a single plane or multiple planes.

Without wanting to be bound by any particular theory, it is believed that including write circuit path 602ws and read circuit path 602rs that each include corresponding separate write transfer data latches 608w and read transfer data latches 608r may increase throughput. Indeed, in the example depicted in FIG. 7C it is believed that the throughput is almost twice the throughput of the example of FIG. 7A for a system that includes a single set of transfer data latches that is shared for read and write operations.

Without wanting to be bound by any particular theory, it is believed that including write circuit path 602ws and read circuit path 602rs that each include corresponding separate write transfer data latches 608w and read transfer data latches 608r may improve bus efficiency and memory bandwidth.

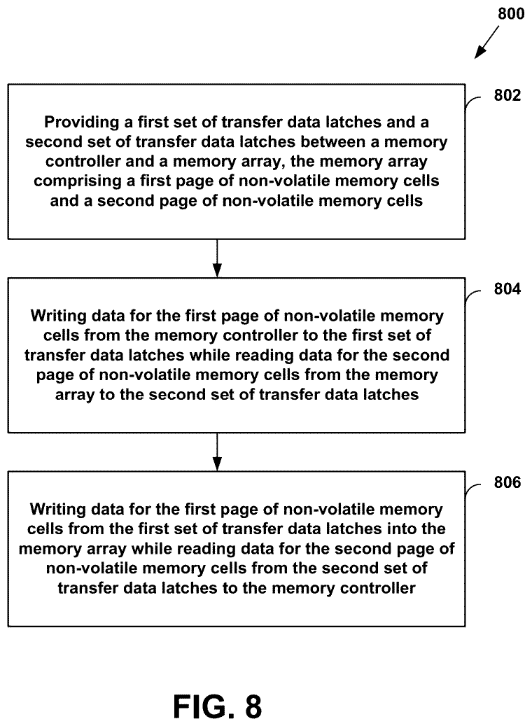

FIG. 8 is a flow diagram of a process 800 for processing program and read operations in a memory array of non-volatile memory cells. In embodiments, process 800 may be performed on one or m ore of memory die 106 (FIG. 1), memory die 200 (FIGS. 2A-2B), memory die 242 (FIGS. 2C-2D), and memory controller 104 (FIGS. 1 and 2A-2D).

At step 802, providing a first set of transfer data latches and a second set of transfer data latches between a memory controller and a memory array, the memory array including a first page of non-volatile memory cells and a second page of non-volatile memory cells.

At step 804, writing data for the first page of non-volatile memory cells from the memory controller to the first set of transfer data latches while reading data for the second page of non-volatile memory cells from the memory array to the second set of transfer data latches.

At step 806, writing data for the first page of non-volatile memory cells from the first set of transfer data latches into the memory array while reading data for the second page of non-volatile memory cells from the second set of transfer data latches to the memory controller.

In an embodiment, an apparatus is provided that includes a memory die including: a memory array having a plurality of non-volatile memory cells, a first set of transfer data latches coupled to the memory array, and a second set of transfer data latches coupled to the memory array. The first set of transfer data latches is configured exclusively for a first type of memory operation, and the second set of transfer data latches is configured exclusively for a first type of memory operation.

In an embodiment, a system is provided that includes a memory array including a plurality of non-volatile memory cells, a memory controller, a first set of transfer data latches coupled between the memory controller and the memory array, and a second set of data latches coupled between the memory controller and the memory array. The first set of transfer data latches is configured for use in all program operations of the memory array, the second set of transfer data latches is configured for use in all read operations of the memory array, and the first set of transfer data latches and the second set of transfer data latches are separate transfer data latches.

In an embodiment, a method is provided that includes providing a first set of transfer data latches and a second set of transfer data latches between a memory controller and a memory array, the memory array including a first page of non-volatile memory cells and a second page of non-volatile memory cells, writing data for the first page of non-volatile memory cells from the memory controller to the first set of transfer data latches while reading data for the second page of non-volatile memory cells from the memory array to the second set of transfer data latches, and writing data for the first page of non-volatile memory cells from the first set of transfer data latches into the memory array while reading data for the second page of non-volatile memory cells from the second set of transfer data latches to the memory controller.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a memory die comprising:
a memory array comprising a plurality of non-volatile memory cells;
a first set of transfer data latches coupled to the memory array; and
a second set of transfer data latches coupled to the memory array,
wherein the first set of transfer data latches is configured exclusively for a first type of memory operation, and the second set of transfer data latches is configured exclusively for a first type of memory operation.

2. The apparatus of claim 1, wherein the first type of memory operation comprises write operations and the second type of memory operation comprises read operations.

3. The apparatus of claim 1, wherein the first set of transfer data latches is different from the second set of transfer data latches.

4. The apparatus of claim 1, wherein the first set of transfer data latches is further configured to receive data to be programmed in the memory array, and provide the received data for programming in the memory array.

5. The apparatus of claim 1, wherein the second set of transfer data latches is further configured to receive data read from the memory array, and provide the data read from the memory array.

6. The apparatus of claim 1, further comprising a memory controller, wherein the first set of transfer data latches is further configured to receive from the memory controller data to be programmed in the memory array.

7. The apparatus of claim 1, further comprising a sense amplifier, wherein the first set of transfer data latches is further configured to provide the sense amplifier data to be programmed in the memory array.

8. The apparatus of claim 1, further comprising a memory controller, wherein the second set of transfer data latches is further configured to provide the memory controller data read from the memory array.

9. The apparatus of claim 1, further comprising a sense amplifier, wherein the second set of transfer data latches is further configured to receive from the sense amplifier data read from the memory array.

10. The apparatus of claim 1, further comprising:
a first circuit path comprising the first set of transfer data latches; and
a second circuit path comprising the second set of transfer data latches.

11. The apparatus of claim 10, wherein:
the first circuit path comprises a write circuit path; and
the second circuit path comprises a read circuit path.

12. A system comprising:
a memory array comprising a plurality of non-volatile memory cells;
a memory controller;
a first set of transfer data latches coupled between the memory controller and the memory array; and
a second set of data latches coupled between the memory controller and the memory array,
wherein:
the first set of transfer data latches is configured for use in all program operations of the memory array;
the second set of transfer data latches is configured for use in all read operations of the memory array; and
the first set of transfer data latches and the second set of transfer data latches are separate transfer data latches.

13. The system of claim 12, wherein the first set of transfer data latches is further configured to receive from the memory controller data to be programmed in the memory array.

14. The system of claim 12, wherein the second set of transfer data latches is further configured to provide the memory controller data read from the memory array.

15. The system of claim 12, further comprising a sense amplifier, wherein the first set of transfer data latches is further configured to provide the sense amplifier data to be programmed in the memory array.

16. The system of claim 12, further comprising a sense amplifier, wherein the second set of transfer data latches is further configured to receive from the sense amplifier data read from the memory array.

17. The system of claim 12, further comprising:
a first circuit path comprising the first set of transfer data latches; and
a second circuit path comprising the second set of transfer data latches.

18. The system of claim 12, further comprising:
a first circuit path comprising the first set of transfer data latches; and
a second circuit path comprising the second set of transfer data latches.

19. The system of claim 18, wherein the first circuit path and the second circuit path do no share transfer data latches.

20. A method comprising:
providing a first set of transfer data latches and a second set of transfer data latches between a memory controller and a memory array, the memory array comprising a first page of non-volatile memory cells and a second page of non-volatile memory cells;
writing data for the first page of non-volatile memory cells from the memory controller to the first set of transfer data latches while reading data for the second page of non-volatile memory cells from the memory array to the second set of transfer data latches; and
writing data for the first page of non-volatile memory cells from the first set of transfer data latches into the memory array while reading data for the second page of non-volatile memory cells from the second set of transfer data latches to the memory controller.
